(19) United States
(12) Patent Application Publication
(10) Pub. No.: US 2025/0196709 A1
(43) Pub. Date: Jun. 19, 2025

(54) BATTERY ASSESSMENT TOOL

(71) Applicant: Smartville, Inc., Carlsbad, CA (US)

(72) Inventors: William von Novak, San Diego, CA (US); Mohamed Afify, Oceanside, CA (US); Antoni Tong, Carlsbad, CA (US); Scott Packard, Carlsbad, CA (US)

(73) Assignee: Smartville, Inc., Carlsbad, CA (US)

(21) Appl. No.: 19/063,170

(22) Filed: Feb. 25, 2025

Related U.S. Application Data
(63) Continuation-in-part of application No. 18/975,819, filed on Dec. 10, 2024.
(60) Provisional application No. 63/610,837, filed on Dec. 15, 2023.

(51) Int. Cl. B60L 58/12; G01R 31/371; G01R 31/3835; G01R 31/396; H01M 10/42

(52) U.S. Cl. CPC B60L 58/12; G01R 31/371; G01R 31/3835; G01R 31/396; H01M 10/4285; B60L 2240/545; B60L 2240/547; H01M 2220/20

(57) ABSTRACT

Systems, methods, and devices are provided for a battery assessment tool for an EV battery. The method of operating a battery assessment tool may comprise receiving, by a controller, a signal from the EV battery. The method may further comprise determining, by the controller, a battery voltage stability, a temperature fluctuation, or a state-of-charge deviation, based on the signal. The method may further include generating a battery status based on a battery safety threshold and at least one of the battery voltage stability, the temperature fluctuation, or the state-of-charge deviation. The method may further comprise indicating, by the battery assessment tool, the battery status of the EV battery. The method may provide information to firefighters, EMTs and other emergency personnel on the safety of the battery in a vehicle they are approaching.

### CROSS-REFERENCE TO RELATED APPLICATIONS

This application is a continuation-in-part of U.S. application Ser. No. 18/975,819, filed Dec. 10, 2024, and entitled “PORTABLE ENABLER FOR EV BATTERY” and claims priority to U.S. Provisional Patent Application No. 63/610,837, filed Dec. 15, 2023 and entitled “PORTABLE ENABLER FOR EV BATTERY,” the disclosures of which are hereby incorporated by reference herein.

### FIELD OF INVENTION

The present disclosure relates generally to a battery monitoring device, and, in particular, to a portable battery assessment tool for an EV battery.

### BACKGROUND

Electric vehicles (“EV”s) are becoming more and more popular around the world, bringing benefits like reduced CO2 emissions, improved acceleration, lower maintenance, and less dependence on greenhouse gas-emitting fossil fuels. While fires involving EVs occur less often than those with internal combustion engines, EV fires present unique challenges for firefighters. Many battery chemistries may not self-extinguish during an overheating or combustion event, and some may generate oxygen during thermal decomposition, making them very difficult to extinguish once combustion has begun. This has led to difficulty in responding to an emergency incident or planning a response to an accident involving an EV.

Thus, there is a need for a tool that allows users, such as firefighters, to assess the fire risk of a suspect EV battery.

### SUMMARY

In an example embodiment, a method assessing a battery status of an electric vehicle (EV) battery is disclosed. The method may include receiving, by a controller, a signal from the EV battery. The method may further include determining, by the controller, a battery voltage stability, a temperature fluctuation, or a state-of-charge deviation based on the signal. The method may further include generating, by the controller, a battery status based on a battery safety threshold and at least one of the battery voltage stability, the temperature fluctuation, or the state-of-charge deviation. The method may further include indicating, by the battery assessment tool, the battery status of the EV battery.

In another example embodiment, a battery assessment tool for an EV battery is disclosed. The battery assessment tool may include a controller in connection with the EV battery. The battery assessment tool may further include a communication interface for receiving a signal from the EV battery and providing the signal to the controller. The controller may be configured to determine a battery voltage stability, a temperature fluctuation, or a state-of-charge deviation based on the signal. The controller may generate a battery status based on a battery safety threshold and at least one of the battery voltage stability, the temperature fluctuation, or the state-of-charge deviation The battery assessment too may further include a display for displaying the battery status of the EV battery.

### BRIEF DESCRIPTION OF THE DRAWING FIGURES

Additional aspects of the present disclosure will become evident upon reviewing the non-limiting embodiments described in the specification and the claims taken in conjunction with the accompanying figures, wherein like numerals designate like elements, and:

FIG. 1 is a diagram illustrating an example battery assessment system, in accordance with various embodiments;

FIG. 2 is a battery assessment tool, in accordance with various embodiments;

FIG. 3 is a battery assessment tool cable system, in accordance with various embodiments; and

FIG. 4 is a flow diagram illustrating an example method, in accordance with various embodiments.

### DETAILED DESCRIPTION

Reference will now be made to the exemplary embodiments illustrated in the drawings, and specific language will be used herein to describe the same. It will nevertheless be understood that no limitation of the scope of the disclosure is thereby intended. Alterations and further modifications of the inventive features illustrated herein, and additional applications of the principles of the disclosure as illustrated herein, which would occur to one skilled in the relevant art and having possession of this disclosure, are to be considered within the scope of the disclosure.

In accordance with an example embodiment, systems, devices and methods are provided for a battery assessment of EV batteries or other suitable batteries comprising internal data communication. In various embodiments, the battery assessment tool may be connected to a battery with an unknown status. For example, when an EV is in an accident, often the battery may be configured to shut off when an impact is detected, via an onboard collision sensor or detection that the airbags have released. The battery may be deactivated by the contactors of the battery being disconnected, or blowing a pyrotechnic fuse, during impact detected by the EV control system. The battery may be disconnected by the EV to prevent exposure to high voltages, thermal runaway, or other issues caused by impact.

The battery assessment tool may allow users, such as firefighters or rescue personnel, to identify potential risks and more safely and effectively plan how to address a damaged EV battery. The battery assessment tool may connect to the EV battery and receive battery information from the EV battery. The battery assessment tool may provide an output of, for example, no action (low-risk battery), careful monitoring while extracting occupants from vehicle (medium-risk battery), or immediate intervention (high-risk battery.) Further, the battery assessment tool may determine how much time until a battery may combust. For example, the battery assessment tool may determine the time until the battery enters thermal runaway, which will allow responders to determine appropriate methods of evacuation of passengers.

The battery assessment tool may determine whether the battery is currently high risk, allowing responders to extinguish the battery if possible. For example, the battery assessment tool may identify the risk of the battery and allow responders to flood or saturate the battery pack in various manners to mitigate thermal runaway events. Alternatively, the battery assessment tool may determine whether the battery is not high risk and destroying the battery through flooding or saturation is not necessary.

In various embodiments, the battery assessment tool may connect to a vehicle either via a cable or wirelessly and allows rescue personnel to determine the safety status of an EV battery. The battery assessment tool may provide the safety status to the rescuer via visual, auditory and/or wireless means.

The battery assessment tool may comprise one or more adapter cables configured to connect with various EVs. The user may determine which adapter cable to use based on the make or model of the EV and may connect the battery assessment tool to the service port, communication port, or other suitable connection port. The battery assessment tool may connect to the Bluetooth or other wireless connection port of the EV, which may increase safety to first responders. Further, the battery assessment tool may connect to the battery communications by the charge port of the EV. For example, the battery assessment tool may connect to the charge port of EVs equipped with Chademo connectors, which allow for connection to the CAN bus from the charge port.

In various embodiments, the battery assessment tool may provide a power source, such as a 12V power source, to the EV battery when the EV battery communication ports are inactive, and/or when the vehicle's battery is not currently enabling the EV battery. Thus, the battery assessment tool is configured to receive communications for the battery when the vehicle and or EV battery is damaged.

In various embodiments, the battery assessment tool may be used to safely determine the risk of the battery. The battery assessment tool may be used by various users, including first responders (firefighters, police, EMS), fleet managers, battery warehousers, and/or car repair/dismantling facilities. In various embodiments, the battery assessment tool may provide the battery risk when the battery is in the EV, such as when the vehicle has been in an accident or collision. In various embodiments, the battery assessment tool may provide the battery risk when the battery is external to the vehicle, in case a battery is dropped or its state is unknown.

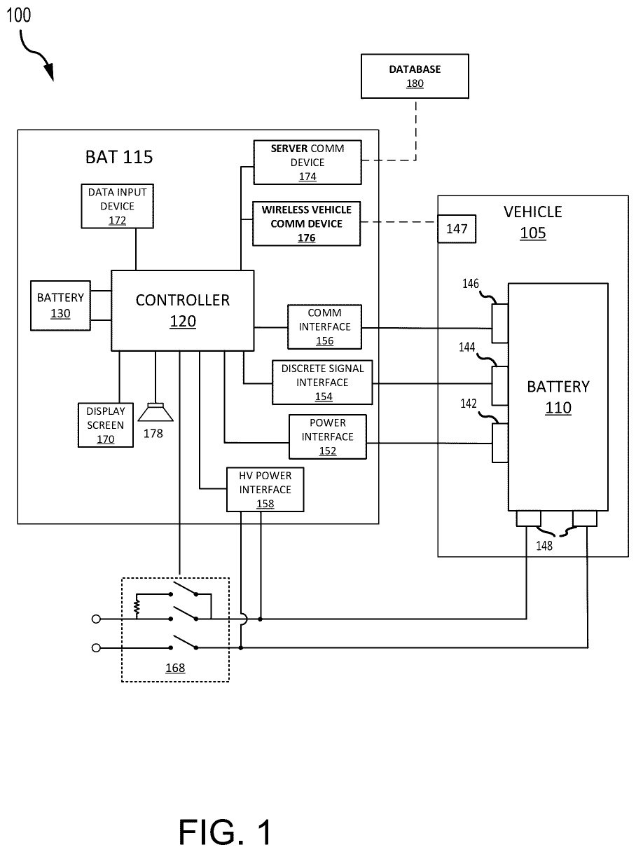

With reference now to FIG. 1, a battery assessment system 100 is illustrated. The battery assessment system 100 may comprise battery 110 and battery assessment tool 115.

In various embodiments, the battery 110 may be an EV battery. In various embodiments, the battery 110 may comprise lithium ion phosphate (LFP) cells, Nickel Cobalt and Aluminum (NCA) cells, or other suitable rechargeable batteries. The battery 110 may be connected to vehicle 105. In various embodiments, the battery 110 may not be connected to a vehicle 105.

In an example embodiment, the battery 110 may comprise a power connector 142, and a signal connector 144, a communication port 146, and/or wireless communication port 147. In various embodiments, the battery 110 may comprise main power output 148. In various embodiments, one or more of the power connector 142, the signal connector 144, and/or the communication port 146 may be combined to a single port on the battery 110. In various embodiments, the battery 110 may be in communication with the battery assessment tool 115 by one or more of the power connector 142, the signal connector 144, and the communication port 146. In various embodiments, the battery assessment tool 115 may be connected to the main power output 148 of the battery 110.

In various embodiments, the battery assessment tool 115 may comprise a controller 120. The controller 120 may be an embedded controller. The battery assessment tool 115 may be portable and lightweight for easy transport and connection to the battery 110. In various embodiments, the controller 120 may be configured to control the various components of the battery assessment tool 115 as described in more detail herein. Further, the controller 120 may be configured to receive signals from the battery 110 and determine the risk associated with the battery 110.

In various embodiments, the battery assessment tool 115 may comprise a battery 130. The battery 130 may be rechargeable. The battery 130 may be 12V or other suitable voltage. The battery assessment tool 115 may be battery powered, so it can be carried to a vehicle that has been in an accident and connected quickly and easily. The battery 130 may power components of the battery assessment tool 115.

In various embodiments, the battery 130 may be configured to receive power from an external power source (not shown). In various embodiments, the battery 130 may receive power from the battery 110. The battery 130 may receive power from the controller 120 which was received from the battery 110.

In various embodiments, the battery assessment tool 115 may comprise one or more connections to the battery 110. In various embodiments, the battery assessment tool 115 may comprise a communication interface 156, discrete signal interface 154, a power interface 152 each for sending and/or receiving signals or power to the battery 110.

In various embodiments, the battery assessment tool 115 may be connected to the battery 110 by a communication interface 156. The communication interface 156 may be used to transfer signals including communication signals between the controller 120 and the battery 110. The communication interface 156 may be electrically connected to the battery 110 by the communication port 146. In various embodiments, the communication port 146 may be a data input or output device. In various embodiments, the communication port 146 may be a Controller Area Network (“CAN”) data bus or other suitable data communication port 146. In various embodiments, the communication interface 156 may be used to send and receive signals from the battery 110. In various embodiments, the communication interface 156 may be configured to provide a CAN interface, NACS interface, an RS485 interface, or any other interface suitable for the battery 110. In various embodiments, the battery assessment tool 115 may send communications or power to the battery 110 to enable the battery 110 to provide signals from the communication port 146. For example, the battery assessment tool 115 may provide power and signals to the battery 110 and in response the battery 110 may provide signals from the communication port 146 to the communication interface 156 of the battery assessment tool 115.

The battery assessment tool 115 may comprise a wireless vehicle communication device 176. The wireless vehicle communication device 176 may be configured to communicate with the wireless communication port 147 of the vehicle 105. The wireless vehicle communication device 176 may be configured to communicate with wireless communication port 147 via Bluetooth, such as OBDII Bluetooth, or other suitable wireless communication protocol. The wireless vehicle communication device 176 may send or receive data or signals from the wireless communication port 147 of the vehicle 105.

In various embodiments, the battery assessment tool 115 may be configured to communicate with the battery 110 by a suitable communication protocol such as CAN ISO 11898-1, High & Low speed CAN ISO 11898-2 ISO 11898-3, OBD Protocols such as ISO 9141-2, ISO 14230-4, SAE J1850, ISO 15765-4 and SAE J1939. In various embodiments, the battery assessment tool 115 may be connected to the battery 110 by any suitable connection, including directly to the charge port (CHAdeMO, CSS1, SCC2, etc.), OBDII Bluetooth connection, or other data information ports of a battery as discussed herein, such as a shared CAN bus.

In various embodiments, the battery assessment tool 115 may comprise a discrete signal interface 154. The discrete signal interface 154 may be configured to provide discrete signals to the battery 110. The discrete signal interface 154 may be connected to the signal connector 144 of the battery 110 or other connector on the battery 110 capable of receiving discrete signals. For example, the battery assessment tool 115 may connect to the contactor or Battery Management System (BMS) of the battery 110 to power the battery 110.

In various embodiments, the battery assessment tool 115 may determine the battery 110 is inactive and the battery assessment tool 115 be configured to activate the battery 110. The battery assessment tool 115 may activate the battery 110 by sending power to the battery 110 to enable and/or energize the battery 110. In various embodiments, the discrete signal interface 154 may send one or more discrete signals to the battery 110. For example, the discrete signal interface 154 may send a first discrete signal to the battery 110 to activate the BMS of the battery 110, allowing external communication with the BMS. As another example, the discrete signal interface 154 may send a first discrete signal to the battery 110 to activate the BMS of the battery 110, and a second discrete signal to activate the main power output 148. In various embodiments, the discrete signal interface 154 may further send additional discrete signals to the battery 110 to enable the battery 110. In various embodiments, the discrete signals sent by the controller 120 to the battery 110 may comprise a signal from an external temperature sensor, or a high voltage interlock signal, or a specific impedance that the main power output 148 needs to receive for the battery 110 to power on.

In various embodiments, the battery assessment tool 115 may be connected to a battery 110 to determine the battery status of the battery 110 based on communications received from one or more of the communication ports. The battery assessment tool 115 may provide an indicator warning based on the battery status. The battery assessment tool 115 may control battery 110 based on the determined status. In various embodiments, the battery assessment tool 115 may deactivate the battery based on the determined battery status. The battery assessment tool 115 may send a command to the battery 110 to open the contactors and/or blow its fuses of the battery 110. In various embodiments, the battery assessment tool 115 may send multiple commands to the battery 110 to deactivate the battery. causing failure. For example, the battery assessment tool 115 may “swamp” the communication port 146 of the battery 110, causing the communications to shut down, in order to cause the battery 110 to respond to this by shutting down.

The battery assessment tool 115 may be configured to receive or determine the battery information associated with the battery 110. Battery information may comprise the battery voltage, battery voltage imbalance, the rate of change of battery voltage, the battery temperature, the rate of change of battery temperature, missing battery information, and/or battery history. For example, the battery assessment tool 115 may determine the battery information based on information received from the communication port 146, and or wireless communication port 147 of the battery 110. For example, the battery assessment tool 115 may determine a battery voltage imbalance based on the battery voltage received from the battery 110. The battery assessment tool 115 may determine rapid changes in battery voltage, rapid temperature increases, missing information and/or battery history based on information received from the communication port 146, and or wireless communication port 147 of the battery 110. For example, the battery voltage imbalance may indicate the battery 110 is damaged, rapid changes in battery voltage may indicate a likely cell short, rapid temperature increases may indicate a thermal runaway event, missing information may be due to destroyed sensors or damaged BMS slave modules, and battery history, such as a rapid change in state-of-charge, may indicate a thermal event. The battery assessment tool 115 may receive this battery information from the battery 110 and determine the risk associated with the battery based on one or more of the battery information.

The battery assessment tool 115 may determine the battery status based on the battery information. The battery assessment tool 115 may determine the risk and amount of time until thermal runaway may occur based on the battery information.

The battery assessment tool 115 may be configured to receive signatures or other battery information that indicates that the battery 110 may be entering thermal runaway. For example, if the battery assessment tool 115 determines the battery 110 is off, but battery temperature is rapidly increasing, a fire is likely. Likewise, if the battery assessment tool 115 determines one cell group of the battery 110 is seeing a rapid decrease in voltage not mirrored by other cell groups, that cell group likely has an internal short. If the battery assessment tool 115 determines many readings are missing (i.e. no cell voltages for a range of cell groups) then it is likely that the battery 110 has severe internal damage. Likewise, if the battery assessment tool 115 determines there is communications sent from the battery 110, such as communication across the CAN bus, but there is no battery 110 activity seen, the battery 110 is likely severely damaged.

The battery assessment tool 115 may identify safety indications. For example, the battery assessment tool 115 may receive information from the communication port 146, such as a CAN bus, which indicates voltage is still present at the output of the terminals of the battery 110, then a warning may be indicated although the battery 110. But if the information received indicates voltage is not present at the output of the terminals, then the battery assessment tool may output that the device appears to be safe.

In various embodiments, the battery assessment tool 115 may enable the battery 110. As described in more detail herein, the battery assessment tool 115 may determine the need to enable the battery 110 in order to obtain communications from the battery 110. In various embodiments, the battery assessment tool 115 may comprise a power interface 152. The power interface 152 may be configured to provide power to the battery 110. In various embodiments, the power interface 152 may be connected to the power connector 142 of the battery 110. In various embodiments, the battery assessment tool 115 may provide power to the battery 110 in the form of 12V DC or other voltage suitable to enable the battery 110. In various embodiments, the controller 120 may send power to the BMS interface of the battery 110 and/or contactors of the battery 110. In various embodiments, the controller 120 may send power directly to the contactors of the battery 110.

In various embodiments, the battery assessment tool 115 may enable various EV batteries by sending one or more discrete signals and/or power to the EV battery. In various embodiments, the battery assessment tool 115 may be configured to enable the battery 110. For example, the battery assessment tool 115 may be connected to an EV battery, such as a Tesla® battery or Nissan Leaf® battery, and sends power or other signals to the battery 110 to enable the battery 110. Once the battery 110 is enabled, the battery 110 may provide a power output from the power connector 142 of the battery 110. The controller 120 may receive the power from the power connector 142 by the power interface 152. In various embodiments, the discrete signal may be a power supply, such as a +12V signal. For example, a Tesla® battery may require two discrete signals to enable the Tesla® battery. In various embodiments, the controller 120 may send two discrete signals to the battery 110. The controller 120 may send a first discrete signal to the discrete signal interface 154 of the battery 110 to power the BMS of the battery 110 and a second discrete signal to the discrete signal interface 154 to power the various internal contactors of the battery 110, and in response the battery 110 may become enabled. After the battery 110 is enabled, the controller 120 may send a CAN bus signal to the communication port 146 of the battery 110 and in response the battery 110 may output power from the main power output 148. In another example, a Nissan Leaf® battery may require four discrete signals to enable the Nissan Leaf® battery. In various embodiments, the controller 120 may send four discrete signals to the battery 110 to enable the battery 110. The controller 120 may send a first discrete signal, a second discrete signal, a third discrete signal and a fourth discrete signal to the discrete signal interface 154 of the battery 110. The first discrete signal may provide power to the BMS of the battery 110, the second discrete signal may energize the internal negative-terminal contactor of the battery 110, the third discrete signal may energize the internal precharge relay of the battery 110 and the fourth may energize the internal positive-terminal contactor of the battery 110. However, in many cases, the battery assessment tool 115 may enable only those portions of the battery 110 that allow the battery assessment tool 115 to communicate with the battery 110.

In various embodiments, the power interface 152 may receive power from the battery 110. In various embodiments, the battery assessment tool 115 may receive power from the power connector 142 to power the battery assessment tool 115. In various embodiments, the power interface 152 may be configured to receive or provide power in the form of 12V or other suitable voltage.

In various embodiments, the battery assessment tool 115 may further comprise a display screen 170. The display screen 170 may be a digital display screen. The controller 120 may control the data displayed on the display screen 170. In various embodiments, the display screen 170 may display the risk associated with a battery 110. In various embodiments, the display screen 170 may show information sent or received by the battery assessment tool 115 to the battery 110.

In various embodiments, the battery assessment tool 115 may comprise a speaker 178. The speaker 178 may be in communication with the controller 120 and configured to receive instructions from the controller 120. The speaker 178 may output an audible signal indicating the battery status or other communications. In various embodiments, the output described herein displayed on the screen 170 may be communicated audibly via speaker 178.

In various embodiments, the battery assessment tool 115 may further comprise a data input device 172. In various embodiments, the data input device 172 may be a keyboard, buttons, switches, or other device capable of selecting and/or entering data into the battery assessment tool 115. The data input device 172 may be in communication with the controller 120. A user may enter information or selections into the data input device 172. The controller 120 may then send or receive power or other communications with the battery 110 in response to the inputs to the data input device 172. The data input device 172 may be configured to receive an input, to turn on/off the battery assessment tool 115, and/or to select data to be displayed on the display screen 170. In an example embodiment, the data input device 172 may be a smartphone or tablet communicating wirelessly or via a wire with the controller 120.

In various embodiments, the battery 110 may comprise a main power output 148. The main power output 148 may output a high current, high voltage power ordinarily suitable for driving the traction motors of an EV. In various embodiments, the main power output 148 may be the main power output of the battery 110 used for powering EVs. In various embodiments, the main power output 148 may be connected to the battery assessment tool 115. In various embodiments, the battery assessment tool 115 may further comprise an impedance network (not shown). The impedance network may be connected to the main power output 148 of the battery 110 and be used to filter the power or provide a specific impedance to the output. The network may comprise capacitors (C) and/or resistors (R) connected to the main power output 148 to filter the power from the battery 110, and provide the correct impedance as seen from the main power output 148. For example, the network may comprise C or RC network connected to the main power output 148, wherein the output from the network may be connected to the battery assessment tool 115 or a test port. In various embodiments, the power from the main power output 148 may be connected to a meter for testing the power output. In various embodiments, the battery assessment tool 115 may further comprise a meter (not shown) for testing power output.

In various embodiments, the battery assessment tool 115 may further and additionally comprise a high voltage (HV) power interface 158. The HV power interface 158 may be connected to the main power output 148 of the battery 110. In various embodiments, the HV power interface 158 may receive high voltage power from the battery 110 and use the power received to power the battery assessment tool 115 and recharge the battery 130. In various embodiments, the HV power interface 158 may be a power converter. For example, the HV power interface 158 may convert the power from the 400V DC received from the battery 110 to a usable 12V DC, or a usable 13.8V DC suitable for charging battery 130.

In various embodiments, the battery assessment tool 115 may further include contactors 168. The contactors 168 may be used to isolate the battery 110 from the output. For example, the contactors 168 may be used between the controller 120 and the battery 110 to disconnect the load from the battery 110 to isolate the battery 110. In various embodiments, the contactors 168 may comprise two high power contactors to allow power flow from the battery 110. In various embodiments, the contactors 168 may comprise a precharge relay to charge up any capacitance that may be placed on the output of the battery assessment tool 115. For example, the contactors 168, including the precharge relay, may allow the battery 110 to output to an external meter or other external load (not shown). The contactors 168 may allow the battery 110 to be isolated so the battery assessment tool 115 may present a desired impedance to the battery 110 even if an external device is connected. In various embodiments, the contactors 168 may be external to the battery assessment tool 115. In various embodiments, the contactors 168 may be in communication with the controller 120 of the battery assessment tool 115 in order to control the contactors 168. In most cases, the battery assessment tool 115 will not close the contactors 168 (if equipped) since external access to the high voltage battery 110 is generally not necessary to determine the safety of the battery 110, and can cause additional risks to emergency personnel.

In various embodiments, the battery assessment tool 115 may further comprise a server communication device 174. The server communication device 174 may be a wireless communication device. For example, the server communication device 174 may comprise a WWAN transmitter (e.g. cellular 4G or 5G communications link, or a satellite communications link) or a WLAN transmitter (e.g. Bluetooth, 802.11 or Zigbee). The server communication device 174 may be in communication with the controller 120 and configured to send and receive information with the controller 120.

The server communication device 174 may connect to the cloud and send battery information to a database 180. The server communication device 174 utilizes previously stored information on that model and/or revision of battery to perform predictive analysis on the future health and/or lifetime of the battery. For example, the controller 120 may receive battery information from the battery 110 and provide battery information to a database 180 through the server communication device 174. The communication device 174 may receive information from the database 180 in response to the battery information provided. For example, the controller 120 may determine the EV battery 110 is a Tesla Model 3® with various measured parameters, including number of times charged, charge percent, etc. The controller 120 may provide this battery information, including the battery history and battery status to the database 180, and in response the database may update predictive battery health models. The predictive battery health model may pass on a plurality of battery history and battery status information to the controller. The database 180 may further comprise information regarding higher risk batteries and how the batteries in a particular EV act to better inform the battery assessment tool 115 of the battery status and risk.

The battery assessment tool 115 may be configured to look up the battery 110 by communication with the database 180. For example, the battery assessment tool 115 may send the battery serial number and/or model number to the database 180, which were received from the battery 110. The battery assessment tool 115 may receive information from the database 180 in response to the battery serial number and/or model number which may be used to determine the battery status. For example, if the battery 110 has been in another vehicle that has been in a crash, or if that model of battery was found to have common problems, that information would be sent from the database 180 to the battery assessment tool 115 and used to determine the battery status. In various embodiments, the database 180 may provide information regarding specific risks associated with a particular battery 110 (i.e. “Cell group 12 is the most often damaged”), which may be used by the battery assessment tool 115 to determine the battery status.

In various embodiments, the server communication device 174 may transmit data to an external device or an external network. For example, a user may use a smart phone to send data to and receive data from the battery assessment tool 115. Additionally, in various embodiments, an external user may remotely monitor the battery assessment tool 115 via the server communication device 174. The controller 120 may intermittently store information of the battery 110 location based on location data from the server communication device 174. Thus, the controller 120 may be configured to store historical location information for the battery 110. In various embodiments, the controller 120 may receive software and data updates over the server communication device 174 to allow for field upgrades and patches.

The external power source may be used to provide power to the battery assessment tool 115. The external power source may be connected to the battery 130 and may provide power and/or charge the battery 130. In various embodiments, the battery assessment tool 115 may use the external power source to provide power to the battery 110. In various embodiments, the battery assessment tool 115 may not include a battery 130 and instead the external power source may connect directly to the controller 120.

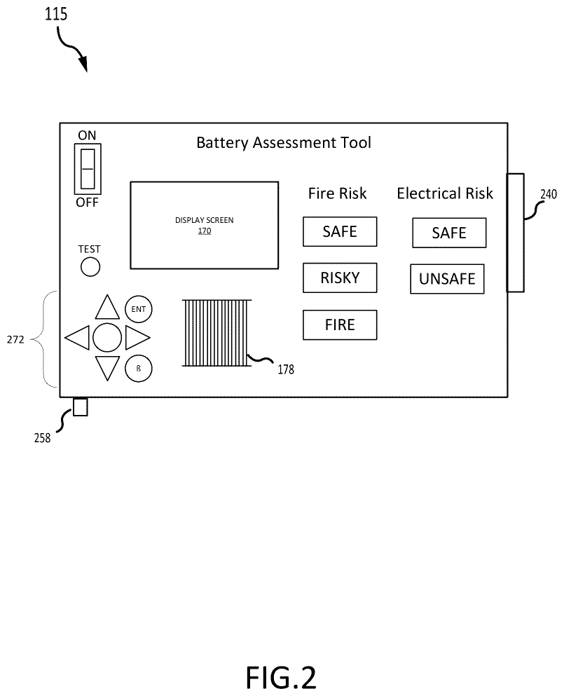

With reference now to FIG. 2, a housing for a battery assessment tool 115 is shown in accordance with various embodiments.

The battery assessment tool 115 may be similar in design to that of FIG. 1. The battery assessment tool 115 may comprise a connector 240. The connector 240 may include the connectors described in reference to FIG. 1. For example, connector 240 may include connectors to connect battery assessment tool 115 to a power connector 142, and a signal connector 144, and/or a communication port 146. The battery assessment tool 115 may include a power button to turn on the battery assessment tool 115. The battery assessment tool 115 may include buttons or switches to turn the battery assessment tool 115 from the ON position to the OFF position. The battery assessment tool 115 may be configured to begin monitoring the battery when the power switch is in the ON position.

The battery assessment tool 115 may include input devices 272, similar to data input device 172 for selecting and inputting data in the battery assessment tool 115. The data input devices 272 may be included as part of the display screen 170. For example, the display screen 170 may be a touch screen and allows data input. The input devices 272 may be used to shut down battery 110. The input devices 272 may be used to scroll through information, such as battery information received from the battery. The input devices 272 may be used to select parameters and make selections. Moreover, any suitable input device may be used to input data and/or command the battery assessment tool 115.

In various embodiments, the battery assessment tool 115 may receive information from the battery 110 via the communication port 146. For example, the controller 120 may receive data and/or signals representative of the current and voltage of the battery 110. The controller 120 may monitor to determine if the temperature is too great, which may indicate thermal runaway. In various embodiments, the controller 120 may monitor the cell voltages of the battery 110 and determine whether the cell voltages are below or above a certain threshold. Additionally, in various embodiments, the controller 120 may determine whether the cell voltage of one cell of the battery 110 is decreasing or dropping much more rapidly than other cell voltages of the battery 110, which would indicate damage or degradation of that cell. In various embodiments, the controller 120 may measure temperature of the battery 110 and/or battery 130, to ensure that the battery is not starting to overheat. Further, in various embodiments, the controller 120 may store temperature, voltage, and current histories, to ensure that the battery has not been mistreated prior to, or during, shipping.

In various embodiments, the controller 120 may receive health/tracking information from the battery 110 via the communication port 146. For example, the controller 120 may receive health tracking, history reports and/or safety indications from the battery 110. Further, the controller 120 may obtain additional information such as the temperature of battery 110, and unique identifiers of the battery 110. The controller 120 may be in communication with smoke, heat and flame detectors that may detect problems at the battery (not shown).

The display screen 170 may display the status of the battery 110. For example, the display screen 170 may display the BMS data of the battery 110. For example, the display screen 170 may display BMS data in a format that a technician can use to decide the health or safety of a battery. The display screen 170 may display data or other information sent or received by the battery assessment tool 115.

The battery assessment tool 115 may comprise one or more indicator lights configured to indicate the battery status. In various embodiments, the battery assessment tool 115 may comprise one or more indicator lights associated with the “fire risk”, such as “SAFE”, “RISKY” and “FIRE.” An indication of “SAFE” may mean the battery is well within normal limits for balance, charge, temperature, etc. An indication of “RISKY” may mean the battery may be within normal limits, but there are trends indicating that it may become unsafe (rising temperature, loss of reporting for one module, etc.). An indication of “FIRE” may indicate the battery is at imminent risk of thermal runaway due to high (sensed) temperatures, imbalance or voltages exceeding safe limits. In various embodiments, the battery assessment tool 115 may comprise one or more indicator lights associated with the “electrical risk”, such as “SAFE” and “UNSAFE.” “SAFE” may indicate the high voltage is not present at the output terminals of the battery. “UNSAFE” may indicate the high voltage is present at the battery's output terminals of the battery. In an example embodiment, if the battery state cannot be determined, the corresponding indicators will not illuminate.

The battery status may be displayed or indicated in any suitable manner. For example, the indicator light may be green, yellow, red to identify the battery status, with green being safe, yellow being questionable, and red being dangerous. In various embodiments, a second indicator will present the state of the external connections of the battery. For example, green for power is off, red for power is on outside the battery.

In various embodiments, the battery assessment tool 115 may comprise a speaker 178. The speaker 178 may output an audible signal indicating the battery status or other communications. For example, the speaker 178 may communicate the fire risk or electrical risk associated with the battery 110. Further the speaker 178 may communicate instructions to the user, such as to connect to the battery 110 in a different manner or to maintain distance from the battery 110.

The battery assessment tool 115 may comprise a TEST button. The TEST button may be used to test the status of the battery. In various embodiments, as discussed, the battery assessment tool 115 may automatically receive communications from the battery and determine the battery status when in proximity to the EV or connected to the EV. However, in various embodiments, the TEST button may be used to instruct the battery assessment tool 115 to test the battery, such as where an additional test may be desired to see if the battery's state has changed.

In various embodiments, the battery assessment tool 115 may include power connector 258. In various embodiments, power connector 258 may connect the battery assessment tool 115 to a power source (not shown). The power source may be used to power the battery assessment tool 115 and enable battery 110, as described with reference to FIG. 1. The battery assessment tool 115 may be housed in a case rugged enough to survive the rigors of use in an outdoor automotive dismantling environment.

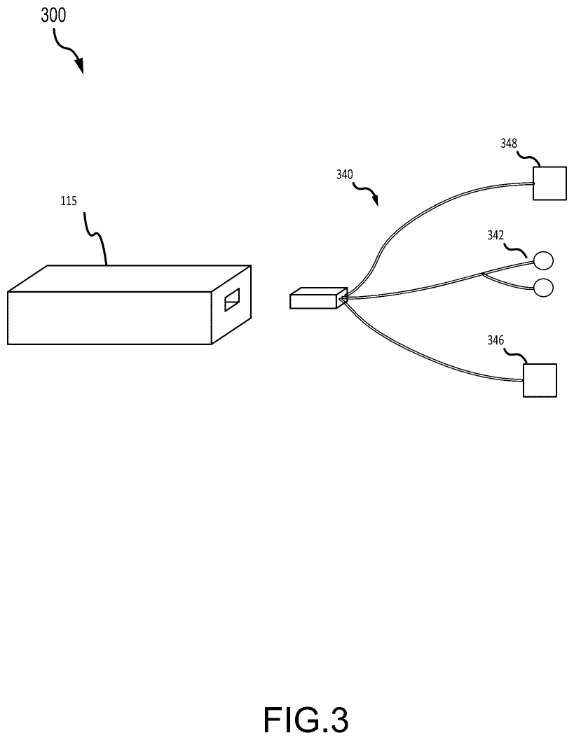

With reference now to FIG. 3, a battery assessment tool cable system 300 is shown in accordance with various embodiments. The cable system 300 includes a cable plug 340 for connecting to the battery 110. In various embodiments, the cable plug 340 may comprise a main power connector 348 for connecting with the main power output 148 of the battery. In various embodiments, the cable plug 340 may include communication connector 346 for connecting to the communication port 146 of the battery 110. In various embodiments, the cable plug 340 may further include a power supply terminal 342 for connecting to the power connector 142 of the battery 110. The cable plug 340 may be removably attached to the battery assessment tool 115. In various embodiments, the cable plug 340 may be connected to the battery assessment tool 115 by a single port on the battery assessment tool 115. In various embodiments, the cable plug 340 may comprise a cable that connects to an OBD-II connector in the vehicle, or to the vehicle's external charge port.

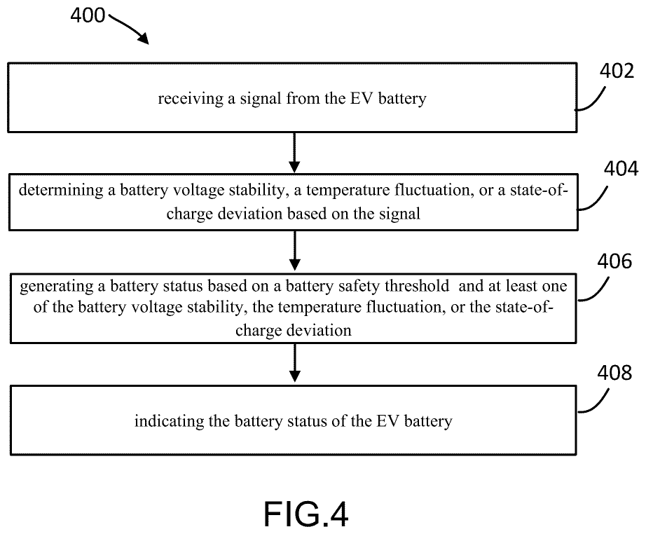

With reference now to FIG. 4, in accordance with an example embodiment, a method 400 of operating a battery assessment tool for an EV battery is disclosed. In various embodiments, method 400 may include receiving, by a controller, a signal from the EV battery (step 402). In various embodiments, method 400 may further comprise determining a battery voltage stability, a temperature fluctuation, or a state-of-charge deviation based on the signal (step 404). In various embodiments, method 400 may further comprise generating a battery status based on a battery safety threshold and at least one of the battery voltage stability, the temperature fluctuation, or the state-of-charge deviation (step 406). The method may further comprise indicating the battery status of the EV battery (step 408).

Example embodiments of the systems, methods, and devices described herein may be implemented in hardware, software, firmware, or some combination of hardware, software, and firmware. For example, the block and schematic diagrams of FIGS. 1-4 may be implemented in hardware, software, firmware, or some combination of hardware, software, and firmware.

In the present disclosure, the following terminology will be used: The singular forms “a,” “an,” and “the” include plural referents unless the context clearly dictates otherwise. Thus, for example, reference to an item includes reference to one or more items. The term “ones” refers to one, two, or more, and generally applies to the selection of some or all of a quantity. The term “plurality” refers to two or more of an item. The term “about” means quantities, dimensions, sizes, formulations, parameters, shapes, and other characteristics need not be exact, but may be approximated and/or larger or smaller, as desired, reflecting acceptable tolerances, conversion factors, rounding off, measurement error and the like and other factors known to those of skill in the art. The term “substantially” means that the recited characteristic, parameter, or value need not be achieved exactly, but that deviations or variations, including, for example, tolerances, measurement error, measurement accuracy limitations and other factors known to those of skill in the art, may occur in amounts that do not preclude the effect the characteristic was intended to provide. Numerical data may be expressed or presented herein in a range format. It is to be understood that such a range format is used merely for convenience and brevity and thus should be interpreted flexibly to include not only the numerical values explicitly recited as the limits of the range, but also interpreted to include all of the individual numerical values or sub-ranges encompassed within that range as if each numerical value and sub-range is explicitly recited. As an illustration, a numerical range of “about 1 to 5” should be interpreted to include not only the explicitly recited values of about 1 to about 5, but also include individual values and sub-ranges within the indicated range. Thus, included in the numerical range are individual values such as 2, 3 and 4 and sub-ranges such as 1-3, 2-4 and 3-5, etc. The same principle applies to ranges reciting only one numerical value (e.g., “greater than about 1”) and should apply regardless of the breadth of the range or the characteristics being described. A plurality of items may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. Furthermore, where the terms “and” and “or” are used in conjunction with a list of items, they are to be interpreted broadly, in that any one or more of the listed items may be used alone or in combination with other listed items. The term “alternatively” refers to selection of one of two or more alternatives and is not intended to limit the selection to only those listed alternatives or to only one of the listed alternatives at a time, unless the context clearly indicates otherwise.

It should be appreciated that the particular implementations shown and described herein are illustrative of the example embodiments and their best mode and are not intended to otherwise limit the scope of the present disclosure in any way. Furthermore, the connecting lines shown in the various figures contained herein are intended to represent exemplary functional relationships and/or physical couplings between the various elements. It should be noted that many alternative or additional functional relationships or physical connections may be present in a practical device.

As one skilled in the art will appreciate, the mechanism of the present disclosure may be suitably configured in any of several ways. It should be understood that the mechanism described herein with reference to the figures is but one exemplary embodiment of the disclosure and is not intended to limit the scope of the disclosure as described above.

It should be understood, however, that the detailed description and specific examples, while indicating exemplary embodiments of the present disclosure, are given for purposes of illustration only and not of limitation. Many changes and modifications within the scope of the instant disclosure may be made without departing from the spirit thereof, and the disclosure includes all such modifications. The corresponding structures, materials, acts, and equivalents of all elements in the claims below are intended to include any structure, material, or acts for performing the functions in combination with other claimed elements as specifically claimed. The scope of the disclosure should be determined by the appended claims and their legal equivalents, rather than by the examples given above. For example, the operations recited in any method claims may be executed in any order and are not limited to the order presented in the claims. Moreover, no element is essential to the practice of the disclosure unless specifically described herein as “critical” or “essential.”

What is claimed:

1. A method of assessing a battery status of an electric vehicle (EV) battery with a battery assessment tool, comprising:
receiving, by a controller, a signal from the EV battery;
determining, by the controller, a battery voltage stability, a temperature fluctuation, or a state-of-charge deviation based on the signal;
generating, by the controller, a battery status based on a battery safety threshold and at least one of the battery voltage stability, the temperature fluctuation, or the state-of-charge deviation; and
indicating, by the battery assessment tool, the battery status of the EV battery.

2. The method of claim 1, further comprising:
providing, by the controller, a power supply to the EV battery; and
transmitting, by the controller, a discrete signal to the EV battery.

3. The method of claim 1, further comprising:
providing, by the controller, the signal from the EV battery to a database;
receiving, by the controller, a battery information from the database;
wherein the battery information comprises data related to the EV battery; and
determining, by the controller, the battery status further based on the battery information.

4. The method of claim 1, further comprising:
providing, by the controller, a deactivation signal to the EV battery based on the battery status.

5. The method of claim 1, wherein the signal comprises a cell voltage of one or more cells of the EV battery, and the battery status is based on the cell voltage.

6. The method of claim 1, wherein the signal comprises one or more voltage measurements of the EV battery, and the battery status is determined based on a voltage trend of the voltages of the EV battery.

7. The method of claim 1, wherein the signal comprises a state-of-charge of the EV battery when the EV battery is in an idle state, and the battery status is determined based on the state-of-charge of the EV battery.

8. The method of claim 1, wherein the signal comprises a temperature measurement associated with the EV battery, and the battery status is based on a rate of change of one or more of the temperature measurements.

9. The method of claim 1, wherein the battery assessment tool communicates with the EV battery by a direct physical connection.

10. The method of claim 1, wherein the battery assessment tool communicates with the EV battery by a wireless connection.

11. The method of claim 1, wherein the battery assessment tool communicates with the EV battery by a charge port of an electric vehicle holding the EV battery.

12. The method of claim 1, wherein the battery assessment tool indicates the battery status by a display.

13. The method of claim 1, wherein the battery assessment tool indicates the battery status by an audible alert.

14. The method of claim 1, wherein the indicating the battery status further comprises providing the battery status to a rescue personnel, wherein the battery status comprises a battery state and a battery safety associated with the EV.

15. A battery assessment tool for an electric vehicle (EV) battery comprising:
a controller in connection with the EV battery;
a communication interface for receiving a signal from the EV battery and providing the signal to the controller;
wherein the controller is configured to determine a battery voltage stability, a temperature fluctuation, or a state-of-charge deviation, based on the signal; and generate a battery status based on a battery safety threshold and at least one of the battery voltage stability, the temperature fluctuation, or the state-of-charge deviation; and
a display for displaying the battery status of the EV battery.

16. The battery assessment tool of claim 15, further comprising:
a power interface electrically connected to the controller and configured to provide a power supply to the EV battery.

17. The battery assessment tool of claim 15, wherein the signal comprises a cell voltage of one or more cells of the EV battery, and the battery status is based on the cell voltage.

18. The battery assessment tool of claim 15, wherein the signal comprises one or more voltage measurements of the EV battery, and the battery status is determined based on a voltage trend of the voltages of the EV battery.

19. The battery assessment tool of claim 15, wherein the signal comprises a state-of-charge of the EV battery when the EV battery is in an idle state, and the battery status is determined based on the state-of-charge of the EV battery.

20. The battery assessment tool of claim 15, wherein the battery assessment tool communicates with the EV battery by a direct physical connection.
